(19) United States
(12) Patent Application Publication
(10) Pub. No.: US 2011/0057207 A1
(43) Pub. Date: Mar. 10, 2011

(54) WHITE-LIGHT EMITTING DEVICE

(75) Inventors: Feng-Cheng Su, Hsinchu County (TW); Cheng-Ta Kuo, Hsinchu City (TW); Chih-Hao Yang, Taipei City (TW)

(73) Assignee: LEXTAR ELECTRONICS CORP., Hsinchu (TW)

(21) Appl. No.: 12/607,068

(22) Filed: Oct. 28, 2009

(30) Foreign Application Priority Data
Sep. 10, 2009 (TW) 98130602

(51) Int. Cl. H01L 33/00

(52) U.S. Cl. 257/88; 257/E33.001

(57) ABSTRACT

An white-light emitting device including a carrier, light emitting diode (LED) chips, and a wavelength converting material is provided. The LED chips are disposed on and electrically connected to the carrier. An equivalent wavelength of the first light emitted from the LED chips and divided into groups is λ. A variation of peak wavelengths of the LED chips in one group is smaller than 5 nm. λ meets an equation:

$$λ = \frac{{\sum }_{1}^{n} ( λ i \times Ni \times Ki )}{{\sum }_{1}^{n} Ni \times Ki}$$

n is an integer equal to or larger than 2. λi, Ni, and Ki are respectively an average peak wavelength, an quantity, and an average output efficiency of the LED chips in one group. The variation of λi in different groups is Δλi. 5 nm≦Δλi≦30 nm. The wavelength converting material is excited by the first light to emit a second light. The first light and the second light are mixed to generate a white light.

### CROSS-REFERENCE TO RELATED APPLICATION

This application claims the priority benefit of Taiwan application serial no. 98130602, filed on Sep. 10, 2009. The entirety of the above-mentioned patent application is hereby incorporated by reference herein and made a part of specification.

### BACKGROUND OF THE INVENTION

1. Field of the Invention

The invention is related to a light emitting device and more particularly, to a white-light emitting device.

2. Description of Related Art

In an light emitting diode (LED), group III-V elements serve as main materials of a light emitting layer, and a current is applied to the light emitting layer. Through combination of electrons and electron holes, redundant energy is released in a form of light, thus achieving a light emitting effect. In comparison with conventional light emission through heating or discharging, the light emitted from the LED is a type of cold emission; therefore, the service life of the LED is rather long, and no idling time is required. In addition, the LED has advantages of high responsive speed, small volume, little consumption of electricity, low degree of pollution (no mercury contained), great reliability, adaptation of mass production, and so on. Thus, applications of the LED are extensive.

Recently, light output efficiency of the LED is continuously increasing, such that conventional fluorescent lamps and incandescent bulbs tend to be gradually replaced by a white-light device using the LEDs serving as a light source of a scanner, a back light source of a liquid crystal display screen, or an illuminator, for example. For example, the white light device is produced by using a blue LED chip and yellow phosphor. The yellow inorganic phosphor can emit a yellow fluorescent light after being irradiated by blue light emitted from the blue LED chip. After the yellow fluorescent light is mixed with the original blue light emitted from the blue LED chip, a white light can be generated.

Conventionally, a wavelength of the light emitted from the blue LED chip is preferable 450 nm to 455 nm for facilitating the yellow phosphor having desirable light output efficiency. Accordingly, the applicable types of the blue LED chips is quite restricted. The wavelengths of the light emitted from the blue LED chips are thus restricted in a small range so that the color rendering property represented by color rendering index (CRI) of the white-light emitting device is not satisfied.

### SUMMARY OF THE INVENTION

The invention provides a white-light emitting device, in which the light emitted from the LED chips has wideband wavelength to represent good color rendering property.

The invention is directed to a white-light emitting device including a carrier, light emitting diode (LED) chips, and a wavelength converting material. The LED chips are disposed on the carrier and electrically connected to the same. An equivalent wavelength of first light emitted from the LED chips is λ. The LED chips are divided into groups. A variation of peak wavelengths of the LED chips in one of the groups is smaller than 5 nm, and λ meets the following equation.

$$λ = \frac{{\sum }_{1}^{n} ( λ i \times Ni \times Ki )}{{\sum }_{1}^{n} Ni \times Ki}$$

In the equation, n is an integer equal to or larger than 2, λi is an average peak wavelength of the LED chips in one group, Ni is a quantity of the LED chips in the one group, Ki is an average output efficiency of the LED chips in the one group, and the variation of the average peak wavelengths of the LED chips in different groups is Δλi, while 5 nm≦Δλi≦30 nm. The wavelength converting material is excited by the first light to emit a second light, and the first light and the second light are mixed to generate a white light.

According to an embodiment of the invention, the carrier includes a circuit board.

According to an embodiment of the invention, the carrier includes a lead frame.

According to an embodiment of the invention, the LED chips are blue LED chips, and the wavelength converting material includes a yellow phosphor.

According to an embodiment of the invention, the quantity of the LED chips in each group is equal to or larger than one.

The invention is also directed to a white-light emitting device including a carrier, a light emitting diode (LED) chip, and a wavelength converting material. The LED chip is disposed on the carrier and electrically connected to the same. An equivalent wavelength of a plurality of first light emitted from the LED chip is λ. The first light emitted from the LED chip are divided into groups. A variation of peak wavelengths of the first light in one of the groups is smaller than 5 nm, and λ meets the following equation.

$$λ = \frac{{\sum }_{1}^{n} ( λ i \times Ri )}{{\sum }_{1}^{n} Ri}$$

In the equation, n is an integer equal to or larger than 2, λi is an average peak wavelength of the first light in one group, Ri is an average output efficiency of the first light in the one group, and the variation of the average peak wavelengths of the first light in different groups is Δλi, while 5 nm≦Δλi≦30 nm. The wavelength converting material is excited by the first light to emit a second light, and the first light and the second light are mixed to generate a white light.

According to an embodiment of the invention, the carrier includes a circuit board.

According to an embodiment of the invention, the carrier includes a lead frame.

According to an embodiment of the invention, the LED chip is a blue LED chip, and the wavelength converting material includes a yellow phosphor.

In view of the above, a plurality of LED chips are used in the invention to generate a mixed light having an equivalent wavelength. The mixed light efficiently excites the wavelength converting material, and is helpful for improving the color rendering property of the white-light emitting device. In addition, a single LED chips emitting light in an equivalent wavelength is also used in the invention for improving the color rendering property of the white-light emitting device.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A illustrates a schematic view of a white-light emitting device according to an embodiment of the invention.

FIG. 1B illustrates a schematic view of a white-light emitting device according to another embodiment of the invention.

FIG. 2 illustrates relationships between the wavelength and the output efficiency of the white-light emitting device according to variation of the average peak wavelengths in different groups.

FIG. 3 illustrates relationships between variation of the average peak wavelengths in different groups and the normalized output efficiency of the white-light emitting device.

FIG. 4 illustrates a schematic view of an LED chip of a white-light emitting device according to another embodiment of the invention.

FIG. 5 illustrates a schematic view of another LED chip of a white-light emitting device according to further another embodiment of the invention.

### DESCRIPTION OF EMBODIMENTS

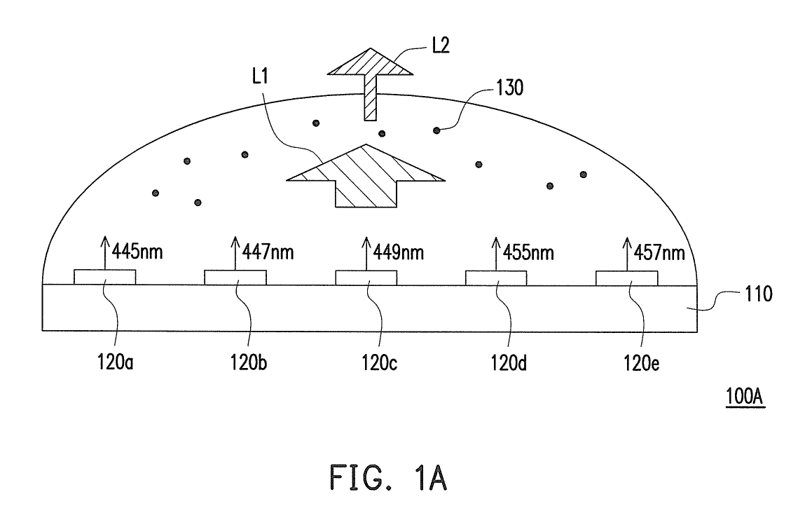

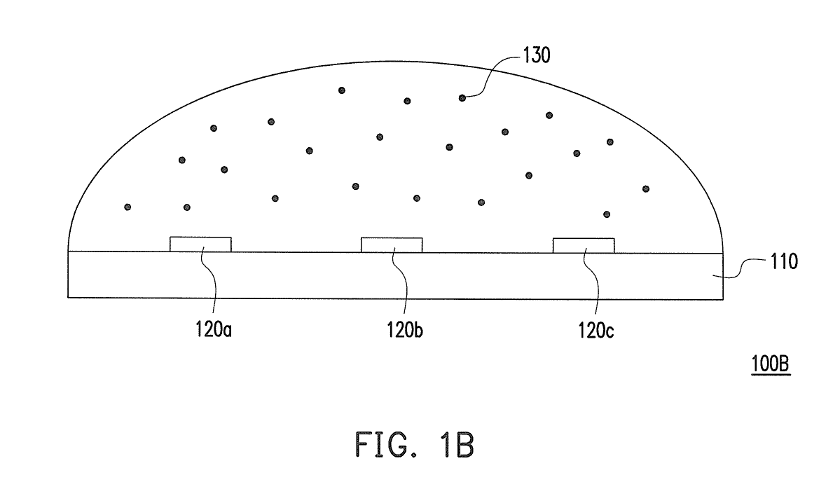

FIG. 1A illustrates a schematic view of a white-light emitting device according to an embodiment of the invention. Referring to FIG. 1A, a white-light emitting device 100A includes a carrier 110, LED chips 120a˜120e, and a wavelength converting material 130. The LED chips 120a˜120e are disposed on the carrier 110 and electrically connected to the same. An equivalent wavelength of first light L1 emitted from the LED chips 120a˜120e is λ. The wavelength converting material 130 is excited by the first light L1 to emit a second light L2, and the first light L1 and the second light L2 are mixed to generate a white light. In the present embodiment, the wavelength converting material 130 is, for example, a phosphor.

Specifically, the LED chips 120a˜120e have slightly different characteristics, in particular, the peak wavelengths of the light emitted from the LED chips 120a˜120e are different. The LED chips 120a˜120e are divided into groups, and a variation of peak wavelengths of the LED chips 120a˜120e in one of the groups is smaller than 5 nm. The peak wavelength is defined as the wavelength of the strongest light emitted from one of the LED chips 120a˜120e.

In addition, λ meets an equation:

$$λ = \frac{{\sum }_{1}^{n} ( λ i \times Ni \times Ki )}{{\sum }_{1}^{n} Ni \times Ki}$$

In the equation, n is an integer equal to or larger than 2, λi is an average peak wavelength of the LED chips 120a˜120e in one group, Ni is a quantity of the LED chips 120a˜120e in the one group, and Ki is an average output efficiency of the LED chips 120a˜120e in the one group. Herein, a variation of the average peak wavelengths of the LED chips 120a˜120e in different groups is Δλi, while 5 nm≦Δλi≦30 nm. In specific, the variation of the average peak wavelengths, that is Δλi, is obtained by subtracting any two average peak wavelengths λi.

In an embodiment, the carrier 110 includes a circuit board or a lead frame. Generally, the circuit boards has a variety of types, such as a glass epoxy resin circuit board (FR-4 and FR-5), a metal core printed circuit board (MCPCB), a ceramic circuit board, or the like. Hence, this embodiment does not restrict the types of the circuit boards to be used.

For emitting a white light, the LED chips 120a˜120e can be blue LED chips, and the wavelength converting material 130 comprises a yellow phosphor. In the present embodiment, the quantity of the LED chips 120a˜120e in each group is equal to or larger than one. That is to say, the white-light emitting device 100A is constituted of at least two or more chips. In fact, five LED chips 120a˜120e are used in the present embodiment, but larger quantity or smaller quantity of the LED chips can be used to form the white-light emitting device 100A in other embodiments. FIG. 1B illustrates a schematic view of a white-light emitting device according to another embodiment of the invention. It is exemplified that three LED chips 120a˜120c are disposed inside the white-light emitting device 100B as shown in FIG. 1B.

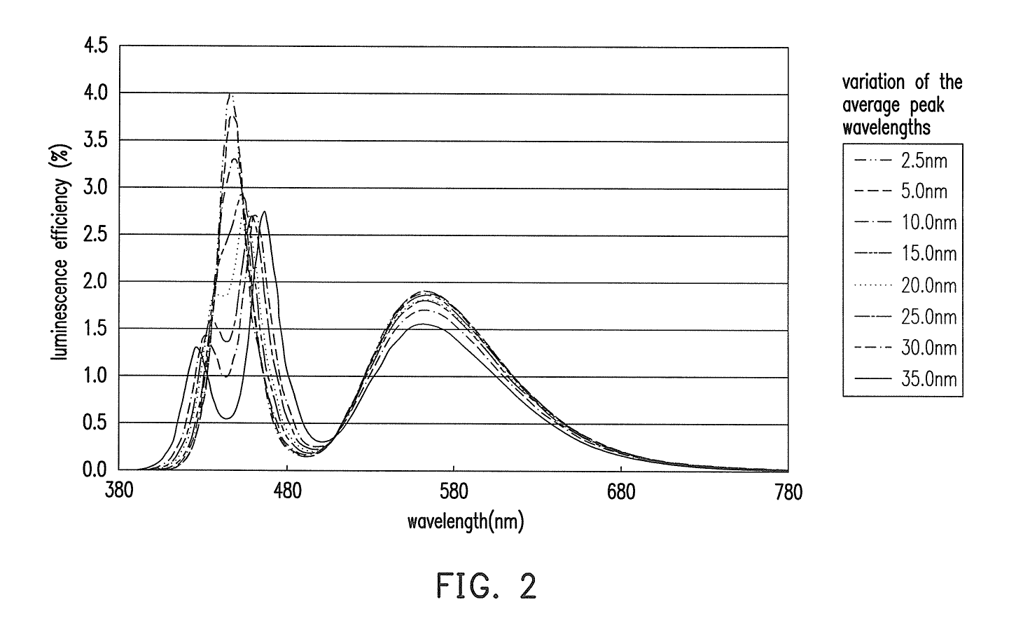

FIG. 2 illustrates relationships between the wavelength and the output efficiency of the white-light emitting device according to variation of the average peak wavelengths in different groups. Referring to FIG. 2, according to the simulation results, the larger the variation of the average peak wavelengths is, the wider the wavelength of the light emitted from the white-light emitting device ranges. Consequently, the white-light emitting device has superior color rendering property.

In other words, different groups of LED chips 120a˜120e are conducive to improve the color rendering property of white-light emitting device 100A. In addition, the simulation result represents that the color rendering index of a conventional white-light emitting device is 62.7, and the color rendering index of the white-light emitting device designed based on the concept of the present embodiment is 68.6 under the same color temperature such as 6,000 K. Accordingly, the white-light emitting device of the present invention can improve the display quality of a display when the white-light emitting device is applied to the display.

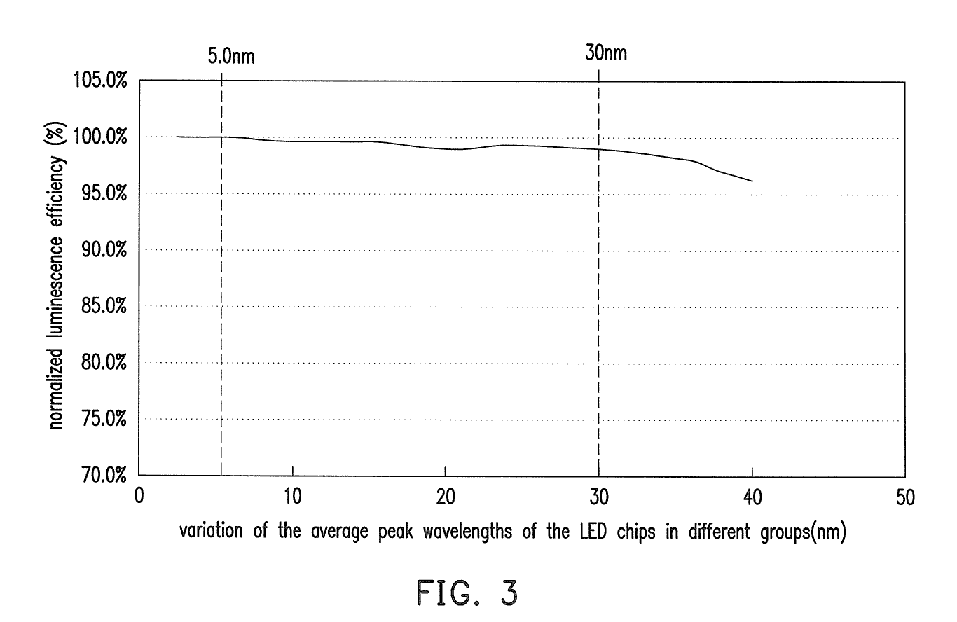

FIG. 3 illustrates relationships between variation of the average peak wavelengths in different groups and the normalized output efficiency of the white-light emitting device. According to FIG. 3, if the variation of the average peak wavelengths is large, the normalized output efficiency of the white-light emitting device may be reduced. Therefore, the variation of the average peak wavelengths in the present embodiment is from 5 nm to 30 nm so that the white-light emitting device 100A or 100B has both good color rendering property and good output efficiency.

Several values are provided hereinafter to elaborate the invention which should not be construed as limited to the values set forth herein. Referring to FIG. 1 continuously, the peak wavelengths of the LED chips 120a˜120e can respectively be 445 nm, 447 nm, 449 nm, 455 nm, and 457 nm. At the same time, the output efficiencies of the LED chips 120a˜120e can be 2.5, 2.4, 2.6, 2.9, and 3.1, respectively. Under such configuration, the LED chips 120a, 120b, and 120c can be demarcated as a first group, and the LED chips 120d and 120e are demarcated as a second group. Herein, the average peak wavelengths λ1 of the LED chips 120a˜120c in the first group is 447 nm, and the average output efficiency K1 thereof is 2.5. The average peak wavelengths λ2 of the LED chips 120d and 120e in the second group is 456 nm, and the average output efficiency K2 thereof is 3.0. In specific, the variation Δλi of the average peak wavelengths between the two groups is the difference of 447 nm and 456 nm, that is 9 nm.

Hence, the equivalent wavelength of the first light L1 is:

$$λ = \frac{( 447 \times 3 \times 2.5 ) + ( 456 \times 2 \times 3.0 )}{( 3 \times 2.5 ) + ( 2 \times 3.0 )} = 451 nm$$

In other words, it is not required that the LED chips 120a˜120e used in the present embodiment have the wavelength of 450 nm to 455 nm to obtain the first light L1 having the equivalent wavelength λ of 450 nm to 455 nm. Therefore, many types of LED chips can be used as the LED chips 120a˜120e of the present embodiment so that the usage of types of the LED chips 120a˜120e applied in the white-light emitting device 100A is much flexible. According to FIG. 2 and FIG. 3, the white-light emitting device 100A has good color rendering property and good output efficiency based on the design. Furthermore, the much flexible usage of types of the LED chips 120a˜120e applied in the white-light emitting device 100A is apt to reduce the manufacturing cost.

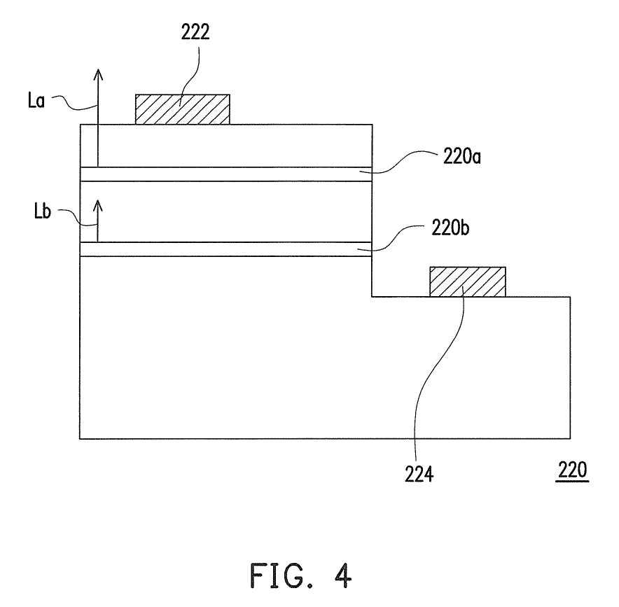

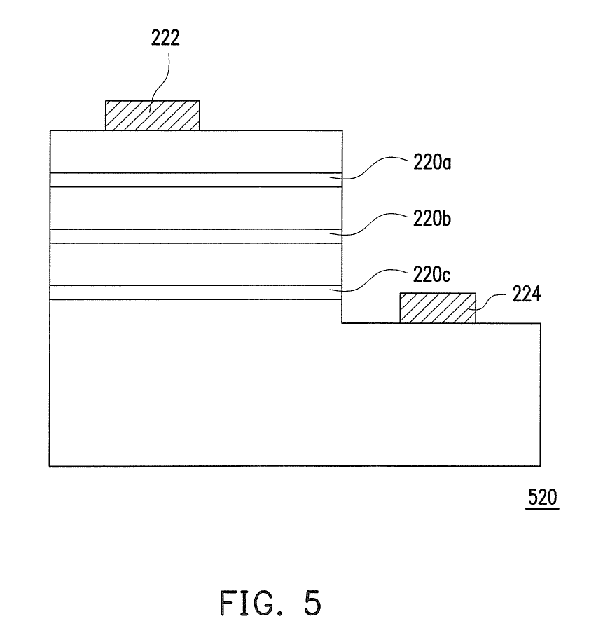

Except the foregoing embodiments, the invention further comprises the following embodiment, wherein the white-light emitting device has only one chip. FIG. 4 illustrates a schematic view of an LED chip of a white-light emitting device according to another embodiment of the invention. Referring to FIG. 4, the LED chip 220 can be applied to the white-light emitting device 100A of FIG. 1A to replace the LED chips 120a˜120e. Specifically, the LED chips 220 has a plurality of light emitting layer such as a first light emitting layer 220a and the second light emitting 220b. In addition, the LED chip 220 has electrodes 222 and 224. The present embodiment takes the chip having two light emitting layers as an example. In other embodiments, the light emitting layers can be more than two. For example, FIG. 5 illustrates a schematic view of another LED chip of a white-light emitting device according to further another embodiment of the invention. The LED chip 520 illustrated in FIG. 5 has three light emitting layers 220a-220c, for example.

Specifically, in the LED chips 220, the first light emitting layer 220a and the second light emitting layer 220b are suitable for emitting the first light La and the first light Lb, respectively. The first light La and Lb emitted from the LED chip 220 are divided into groups. A variation of peak wavelengths of the first light La and Lb in one of the groups is smaller than 5 nm. In addition, the equivalent wavelength of the first light La and Lb is 2 which meets an equation:

$$λ = \frac{{\sum }_{1}^{n} ( λ i \times Ri )}{{\sum }_{1}^{n} Ri}$$

In the equation, n is an integer equal to or larger than 2, λi is an average peak wavelength of the first light La and Lb in one group, Ri is an average output efficiency of the first light La and Lb in the one group, and the variation of the average peak wavelengths of the first light La and Lb in different groups is Δλi, while 5 nm≦Δλi≦30 nm.

In view of the foregoing embodiment, it is helpful for improving the color rendering property of the white-light emitting device by mixing different groups of the light to accomplish the needed wavelength. In addition, the variation of the average peak wavelengths of the first light La and Lb in one of the groups is located in a limited range, therefore, the output efficiency of the LED chip 220 still maintains in an ideal state.

In light of the foregoing, the white-light emitting device has good color rendering property by using a plurality of LED chips or disposing a plurality of light emitting layers in a single LED chip. The invention provides a white-light emitting device, in which the usage of the types of the LED chips is much flexible to facilitate mass production.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A white-light emitting device, comprising:
a carrier;
a plurality of light emitting diode (LED) chips disposed on the carrier and electrically connected to the carrier, wherein an equivalent wavelength of first light emitted from the LED chips is λ, the LED chips are divided into a plurality of groups, a variation of peak wavelengths of the LED chips in one of the groups is smaller than 5 nm, and λ meets an equation:
$$λ = \frac{{\sum }_{1}^{n} ( λ i \times Ni \times Ki )}{{\sum }_{1}^{n} Ni \times Ki}$$
wherein n is an integer equal to or larger than 2, λi is an average peak wavelength of the LED chips in one of the groups, Ni is a quantity of the LED chips in the one group, Ki is an average output efficiency of the LED chips in the one group, and the variation of the average peak wavelengths of the LED chips in different groups is Δλi, while 5 nm≦λi≦30 nm; and
a wavelength converting material, wherein the wavelength converting material is excited by the first light to emit a second light, and the first light and the second light are mixed to generate a white light.

2. The white-light emitting device according to claim 1, wherein the carrier comprises a circuit board.

3. The white-light emitting device according to claim 1, wherein the carrier comprises a lead frame.

4. The white-light emitting device according to claim 1, wherein the wavelength converting material comprises a phosphor.

5. The white-light emitting device according to claim 1, wherein the light emitting diode chips are blue light emitting diode chips, and the wavelength converting material comprises a yellow phosphor.

6. The white-light emitting device according to claim 1, wherein the quantity of the LED chips in each group is equal to or larger than one.

7. A white-light emitting device, comprising:
a carrier;
a light emitting diode (LED) chip disposed on the carrier and electrically connected to the carrier, wherein an equivalent wavelength of a plurality of first light emitted from the LED chip is λ, the first light emitted from the LED chip are divided into a plurality of groups, a variation of peak wavelengths of the first light in one of the groups is smaller than 5 nm, and λ meets an equation:
$$λ = \frac{{\sum }_{1}^{n} ( λ i \times Ri )}{{\sum }_{1}^{n} Ri}$$
wherein n is an integer equal to or larger than 2, λi is an average peak wavelength of the first light in one of the group, Ri is an average output efficiency of the first light in the one group, and the variation of the average peak wavelengths of the first light in different groups is Δλi, while 5 nm≦Δλi≦30 nm; and
a wavelength converting material, wherein the wavelength converting material is excited by the first light to emit a second light, and the first light and the second light are mixed to generate a white light.

8. The white-light emitting device according to claim 7, wherein the carrier comprises a circuit board.

9. The white-light emitting device according to claim 7, wherein the carrier comprises a lead frame.

10. The white-light emitting device according to claim 7, wherein the light emitting diode chip is a blue light emitting diode chip, and the wavelength converting material comprises a yellow phosphor.
